(19) United States
(12) Patent Application Publication
(10) Pub. No.: US 2025/0355427 A1
(43) Pub. Date: Nov. 20, 2025

(54) SYSTEM AND METHODS FOR WIRING WORKING BENCHES

(71) Applicant: Polygon T.R Ltd., Tzur-Yigal (IL)

(72) Inventors: Omer EINAV, Kfar-Monash (IL); Rom EISENBERG, Kfar-Saba (IL); Doron SHABANOV, Tzur-Yigal (IL)

(73) Assignee: Polygon T.R Ltd., Tzur-Yigal (IL)

(21) Appl. No.: 18/866,538

(22) PCT Filed: May 9, 2023
(86) PCT No.: PCT/IL2023/050473

§ 371 Date: Nov. 17, 2024

Related U.S. Application Data
(60) Provisional application No. 63/342,668, filed on May 17, 2022.

(51) Int. Cl. G05B 19/418; H05K 13/00; H05K 13/08

(52) U.S. Cl. CPC G05B 19/41875; G05B 19/41865; H05K 13/0053; H05K 13/081

(57) ABSTRACT

An aspect of the invention relates to a mobile factory system comprising one or more mobile factories, each comprising at least one workbench comprising at least one screen on which guiding-assembling instructions of an assembling process are shown and circuitry comprising a memory and instructions to provide and monitor said guiding-assembling instructions of an assembling process through said at least one screen.

### RELATED APPLICATION/S

This application claims the benefit of priority of U.S. Provisional Patent Application No. 63/342,668 filed on 17 May 2022, the contents of which are incorporated herein by reference in their entirety.

### FIELD AND BACKGROUND OF THE INVENTION

The present invention, in some embodiments thereof, relates to system and methods of wiring working benches and, more particularly, but not exclusively, to system and methods for mobile wiring working benches.

Additional background art includes s U.S. Patent Application Publication No. US20190105779A1 disclosing robotic systems for simultaneous human-performed and robotic operations within a collaborative workspace. In some embodiments, the collaborative workspace is defined by a reconfigurable workbench, to which robotic members are optionally added and/or removed according to task need. Tasks themselves are optionally defined within a production system, potentially reducing computational complexity of predicting and/or interpreting human operator actions, while retaining flexibility in how the assembly process itself is carried out. In some embodiments, robotic systems comprise a motion tracking system for motions of individual body members of the human operator. Optionally, the robotic system plans and/or adjusts robotic motions based on motions which have been previously observed during past performances of a current operation.

U.S. Patent No. U.S. Pat. No. 11,110,610B2 disclosing a workbench system comprising: a workbench; a multi-axis robot; a visible light projector; and a controller; wherein the workbench and the robot are located in a common workspace; the controller is configured to: determine a movement operation for the robot; and, using the determined movement operation, control the visible light projector to project a visible light indication onto at least one of a surface of the workbench and a surface of the workspace; the visible light indication indicates a limited area of the workbench and/or workspace, the limited area corresponding to a limited volume of space; and the movement operation is such that, if the robot performs the movement operation, the robot moves entirely within only the limited volume of space.

U.S. Patent No. U.S. Pat. No. 10,780,536B2 disclosing an automated assembly apparatus comprising an assembly robot that includes a Y-axis movement unit, a first X-axis movement unit movable in a Y-axis direction along the Y-axis movement unit, and a grip unit movable in an X-axis direction along the X-axis movement unit, and a workbench unit including a Z-axis movement unit arranged below the assembly robot with respect to an Z-axis and a workbench movable in the Z-axis direction along the Z-axis movement unit, wherein an assembly operation for a first assembly component gripped by the grip unit and a second assembly component mounted on the workbench unit is performed through movement in the Z-axis direction by the workbench unit.

U.S. Patent No. U.S. Pat. No. 10,300,597B2 disclosing a robot including a base, a body connected to the base, a pair of articulated arms rotatably connected to the body, and a moving mechanism adapted to move the body toward or away from the base. Further, a relative positional relationship with a workbench is detected by moving the body with respect to the base using the moving mechanism while keeping the articulated arms in predetermined postures while facing the workbench, and then making the articulated arms contact the workbench.

U.S. Patent No. U.S. Pat. No. 10,252,384B2 disclosing an automated assembly apparatus comprising an assembly robot that includes a Y-axis movement unit, a first X-axis movement unit movable in a Y-axis direction along the Y-axis movement unit, and a grip unit movable in an X-axis direction along the X-axis movement unit, and a workbench unit including a Z-axis movement unit arranged below the assembly robot with respect to an Z-axis and a workbench movable in the Z-axis direction along the Z-axis movement unit, wherein an assembly operation for a first assembly component gripped by the grip unit and a second assembly component mounted on the workbench unit is performed through movement in the Z-axis direction by the workbench unit.

U.S. Patent No. U.S. Pat. No. 9,548,168B2 disclosing a robot that includes a power source of the robot, and a switch section adapted to block electrical power supply to the power source. The switch section is disposed on a front side of the robot arranged to face to a workbench when at work. The switch section blocks the electrical power supply to the power source in a case in which it is detected that a distance between the robot and the workbench is longer than a predetermined distance.

U.S. Patent No. U.S. Pat. No. 9,381,641B2 disclosing a robot that includes a base, a body connected to the base, a pair of articulated arms rotatably connected to the body, and a moving mechanism adapted to move the body toward or away from the base. Further, a relative positional relationship with a workbench is detected by moving the body with respect to the base using the moving mechanism while keeping the articulated arms in predetermined postures while facing the workbench, and then making the articulated arms contact the workbench.

U.S. Patent No. U.S. Pat. No. 9,037,289B2 disclosing a processing system comprising an article supplier which supplies an article; a first conveyor which conveys an object to be processed; a workbench which is provided on the downstream side of the first conveyor and places thereon the object to be processed, conveyed by the first conveyor; a robot which takes out the article from the article supplier and subjects the object to be processed, placed on the workbench, to an operation using the article according to a previously instructed operation movement; and a second conveyor which is provided on the downstream side of the workbench and conveys the object to be processed, which has been subjected to the operation by the robot.

### SUMMARY OF THE INVENTION

Following is a non-exclusive list including some examples of embodiments of the invention. The invention also includes embodiments which include fewer than all the features in an example and embodiments using features from multiple examples, also if not expressly listed below.

Example 1. A workbench for guided-assembling a product, comprising:
a. a surface on which said product is assembled;
b. at least one screen on which guiding-assembling instructions of an assembling process are shown;
c. circuitry comprising a memory and instructions to provide and monitor said guiding-assembling instructions of an assembling process through said at least one screen.

Example 2. The workbench according to example 1, wherein said circuitry comprises instructions to monitor an execution of said assembling process for validating and/or improving one or more of: quality assurance (QA), cycle time and use of raw materials.

Example 3. The workbench according to example 1 or example 2, further comprising a laser guiding system configured to guide a user during said assembling process.

Example 4. The workbench according to anyone of examples 1-3, further comprising at least one camera configured for monitoring actions performed during said assembling process.

Example 5. The workbench according to anyone of examples 1-4, wherein said workbench is provided with a connection to at least one remote assistant for assisting in said assembling process.

Example 6. The workbench according to anyone of examples 1-5, wherein said remote assistant has access to said at least one camera and said at least one screen.

Example 7. The workbench according to anyone of examples 1-6, further comprising additional tools required for said assembling process.

Example 8. The workbench according to anyone of examples 1-7, wherein said product is one or more of an electrical panel, an electrical cabinet, a lighting body and an electronic appliance.

Example 9. The workbench according to anyone of examples 1-8, wherein said assembling process comprises wiring components in said product.

Example 10. The workbench according to anyone of examples 1-9, wherein said instructions are generated based on optimized assembling process generated by one or more of: an expert, a computer having dedicated software comprising instructions to generate said optimized assembling process.

Example 11. A mobile factory comprising:
a. a structure with a roof and walls sized and shaped to be mobilized from one location to another using at least one means of transportation;
b. one or more workbenches as disclosed in example 1.

Example 12. The mobile factory according to example 11, wherein said at least one means of transportation is a truck.

Example 13. A mobile factory system, comprising:
a. one or more mobile factories as disclosed in example 11;
b. at least one central server comprising instructions to manage job activities and locations of said one or more mobile factories.

Example 14. The mobile factory system according to example 13, further comprising at least one remote one remote assistant, according to example 5, for remotely assisting in assembling processes in said one or more mobile factories.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

As will be appreciated by one skilled in the art, some embodiments of the present invention may be embodied as a system, method or computer program product. Accordingly, some embodiments of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, some embodiments of the present invention may take the form of a computer program product embodied in one or more computer readable medium(s) having computer readable program code embodied thereon. Implementation of the method and/or system of some embodiments of the invention can involve performing and/or completing selected tasks manually, automatically, or a combination thereof. Moreover, according to actual instrumentation and equipment of some embodiments of the method and/or system of the invention, several selected tasks could be implemented by hardware, by software or by firmware and/or by a combination thereof, e.g., using an operating system.

For example, hardware for performing selected tasks according to some embodiments of the invention could be implemented as a chip or a circuit. As software, selected tasks according to some embodiments of the invention could be implemented as a plurality of software instructions being executed by a computer using any suitable operating system. In an exemplary embodiment of the invention, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

Any combination of one or more computer readable medium(s) may be utilized for some embodiments of the invention. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electromagnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium and/or data used thereby may be transmitted using any appropriate medium, including but not limited to wireless, wireline, optical fiber cable, RF, etc., or any suitable combination of the foregoing.

Computer program code for carrying out operations for some embodiments of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Some embodiments of the present invention may be described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Some of the methods described herein are generally designed only for use by a computer, and may not be feasible or practical for performing purely manually, by a human expert. A human expert who wanted to manually perform similar tasks, might be expected to use completely different methods, e.g., making use of expert knowledge and/or the pattern recognition capabilities of the human brain, which would be vastly more efficient than manually going through the steps of the methods described herein.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic representation of an exemplary system, according to some embodiments of the invention;

FIG. 2 is a schematic representation of a mobile factory showing a plurality of workbenches, according to some embodiments of the invention;

FIG. 3 is a schematic representation of a plurality of mobile factories and exemplary remote support, according to some embodiments of the invention;

FIGS. 4a-i are schematic representations of exemplary workbenches, according to some embodiments of the invention;

FIGS. 5a-d are schematic representations of exemplary steps in the production including logistics, according to some embodiments of the invention;

FIG. 6 is a schematic representation of an exemplary user interface displayed on a screen, according to some embodiments of the invention;

FIG. 7 is a flowchart of an exemplary method of setting a new job in the system, according to some embodiments of the invention; and

FIG. 8 is a flowchart of an exemplary method of accessing a job in the system, according to some embodiments of the invention.

### DESCRIPTION OF SPECIFIC EMBODIMENTS OF THE INVENTION

The present invention, in some embodiments thereof, relates to system and methods of wiring working benches and, more particularly, but not exclusively, to system and methods for mobile wiring working benches.

### Overview

An aspect of some embodiments of the invention relates to mobile factories comprising working benches configured to guide low-skilled users in the process of assembly. In some embodiments, the mobile factories comprise all necessary equipment for the full functioning of the factory. In some embodiments, the mobile factory is supplied with raw materials as needed. In some embodiments, the mobile factories are placed in locations that are attractive to the potential population of workers. In some embodiments, the mobile factories are operational 24 hours a day in order to allow flexibility of shift to the workers. In some embodiments, the workbench comprise at least one screen configured to show the worker the assembly steps. In some embodiments, the workbench comprises a vision module configured to monitor the work that is performed by the worker. In some embodiments, the workbench optionally comprises a laser guiding system configured to assist the worker in the assembly process. In some embodiments, quality is assured by monitoring the work performed by the worker. In some embodiments, quality is assured by providing easy-to-follow instructions to the worker. In some embodiments, remote assistance is provided to the worker in case of need by means of the screen and the visual module.

An aspect of some embodiments of the invention relates to mobile factories comprising wiring working benches configured to guide low-skilled users in the process of wiring electrical panels. In some embodiments, guiding of low-skilled users is enabled by providing easy-to-follow wiring instructions received from one or more of screens, speakers, laser guiding system, visual system and dedicated personnel located remotely and/or in site. In some embodiments, the wiring instructions are based on optimized algorithms of wiring, which take under consideration one or more of the number of components needed to be wired, the space in the electrical panel/cabinet/lightning body/appliance, the number of bin rails and the type of wires. In some embodiments, the unexperienced worker receives simple wiring directions while keeping the worker from dealing with the complex task of planning the wiring of the product. In some embodiments, the optimization comprises the use of AI and/or learning algorithms.

An aspect of some embodiments of the invention relates to a “ghost factory” that provides quick set up for flexible workforce at any location. In some embodiments, the factory is provided with one or more computerized guiding workbenches for workers doing assembly, wiring, inspection and packaging (e.g. control panels, mechanical assembly, etc.). In some embodiments, the workers are low-skilled workers and/or low-experienced workers. In some embodiments, the factory is set-up in the vicinity of the location where workers are available. In some embodiments, the factory is set-up near logistic centers where parts required in the factory are supplied. In some embodiments, the factory is set-up near the near-end users requiring the end product generated in the factory. In some embodiments, the work-hours are flexible to the personal schedule of the workers. In some embodiments, the one or more computerized workbenches provide simple instructions on a screen and, optionally, laser projected lines are used to guide the users during the actions requested of them. In some embodiments, the one or more computerized workbenches comprise live interactive assembly instructions/guidance, validation performance and testing. In some embodiments, on-going improvement monitoring is used to improve and provide consistent outcome of the work (for example, quality and throughput). In some embodiments, the one or more computerized workbenches are configured for teach mode and are set-up to allow new workers with minimal or no-experience to begin working in a fast manner. In some embodiments, support and supervision are provided remotely via individual screens in each workbench. In some embodiments, optionally, a dedicated app/website is used for the scheduling of the working hours of the workers. In some embodiments, the system is configured to provide high level performance guidance with personal fit for the required job. In some embodiments, the factory is a mobile factory and it is configured to have a flexible and easy set-up, meaning it can be deployed anywhere and can do any kind of assembly, inspection, packing electrical wiring and various other job.

An aspect of some embodiments of the invention relates to a system for work distribution, scheduling, management a quality assurance. In some embodiments, the system comprises an app/website/software for work set up, scheduling support and a friendly assembly workbench with interactive instructions and visual guidance providing a functioning work environment anytime and anywhere with high-quality and throughput. In some embodiments, workers can be one or more of unskilled employees, students, part-timers, handicap people, and teenagers looking a job. In some embodiments, a potential advantage of the system is that it potentially provides a solution for shortage in “working hand”, allowing virtual employment for all types of workers with controlled quality and consistent throughputs. In some embodiments, the system is configured to be set at any location (for example: work near the workers, near a plant, near a location with logistic constrains, overseas). In some embodiments, the system is configured to maintain high quality and high throughput with flexibility. In some embodiments, another potential advantage of the system is that it potentially generates a distributed manufacturing capacity, which is currently untapped. In some embodiments, the system is configured to enable a built-in improvement mechanism thru improving the employees' skills, making them a better fit for the job. In some embodiments, in addition the system is provided with better logistics, which overall enables higher throughput.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

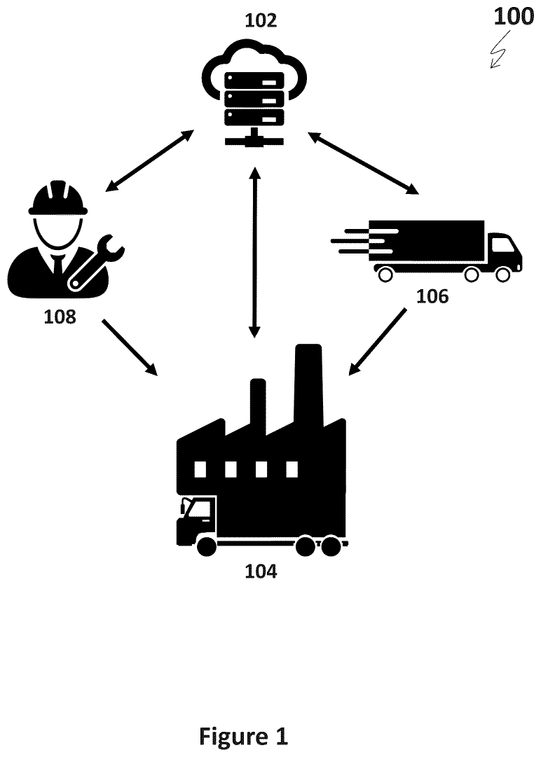

Referring now to FIG. 1 showing a schematic representation of an exemplary system, according to some embodiments of the invention. In some embodiments, the system 100 comprises a central server 102 from which the whole system 100 is controlled/monitored. In some embodiments, the central server 102 is a cloud-based server. In some embodiments, the system comprises a plurality of mobile factories 104 that can be moved from one location to another according to the instructions received from the central server 102. In some embodiments, the central server 102 coordinates delivery of materials from one or more suppliers 106 to the plurality of mobile factories 104, wherever they are located. In some embodiments, the central server also coordinates the schedule of workers 108 that will come to work in the mobile factories 104. In some embodiments, the mobile factories are used for the assembly and preparation of electrical cabinets. While the following disclosure will use the example of preparation of electrical panels, it will be obvious to a person having skills in the art that other products can be prepared and assembled in similar mobile factories, and therefore, the following explanations, while directed to the assembly and preparation of electrical cabinets, should not be limited to those alone, and other products are intended to be covered by the present invention.

### Exemplary Mobile Factories 104

In some embodiments, the system utilizes a plurality of mobile factories 104 for the assembly and preparation of products. In some embodiments, those products are electrical panels and/or electrical cabinets. In some embodiments, those products can be any product that require some level of assembly.

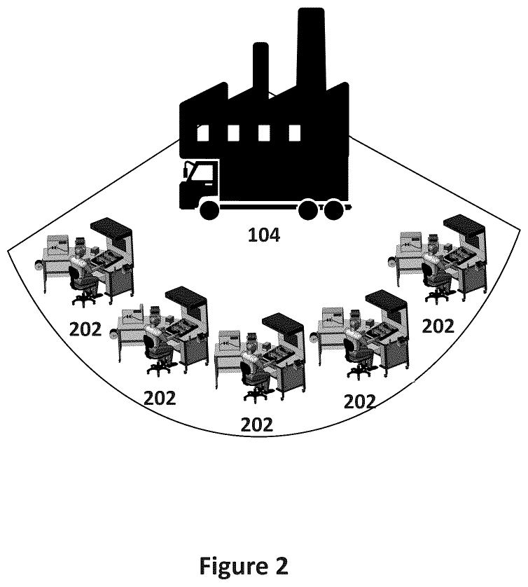

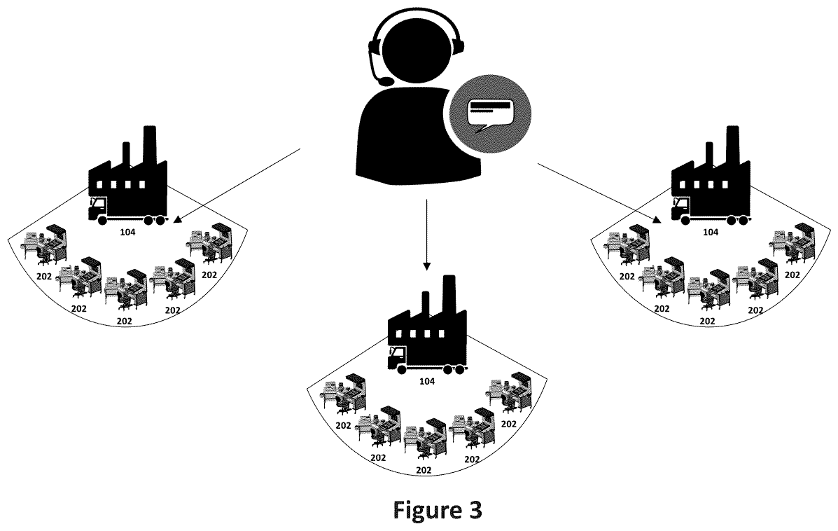

Referring now to FIG. 2 showing a schematic representation of a mobile factory showing a plurality of workbenches, according to some embodiments of the invention. In some embodiments, the mobile factories 104 comprise one or more workbenches 202. In some embodiments, each workbench in each mobile factory comprises means of communication (for example, a computer with a webcam and microphone) that allows communication with a supervisor and/or remote support, which is located remotely, as schematically shown in FIG. 3. While FIG. 3 shows one remote support image, it should be understood that remote support can comprise a plurality of technical personnel located remotely, for example, experienced technical personnel can sit at home or at dedicated offices. In some embodiments, dedicated experienced personnel can provide support to one or more workbenches. In some embodiments, dedicated experienced personnel can provide support to one or more mobile factories at the same time. In some embodiments, additionally, one experience worker in one workbench can support and/or demonstrate proper work process to a pier in a different workbench thus creating non supervised ad hock support, optionally one worker can raise a question and/or “post” improvement supporting other employees (creating on going improvement).

In some embodiments, mobile factories include one or more mangers responsible for the mobile factory. In some embodiments, the mobile factory includes a storage area for the raw materials used in the workbenches. In some embodiments, usage of raw materials are monitored, for example by using RF technology or by manually scanning items being taken from the storage location in the mobile factory or by any other means of monitoring raw materials/consumables known in the art.

### Exemplary Workbench

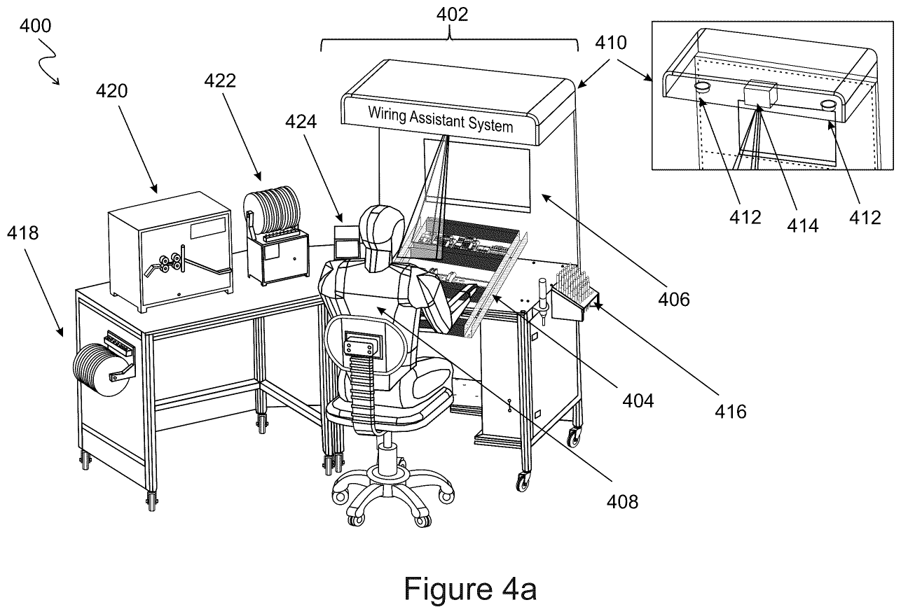

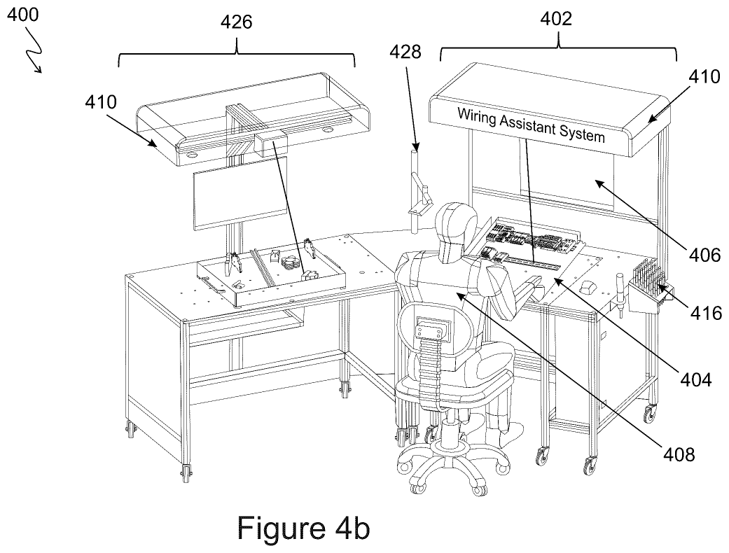

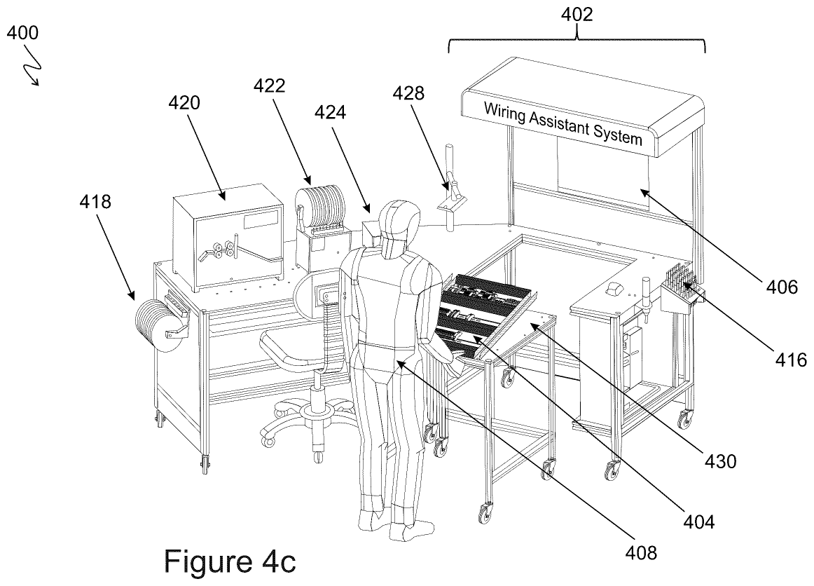

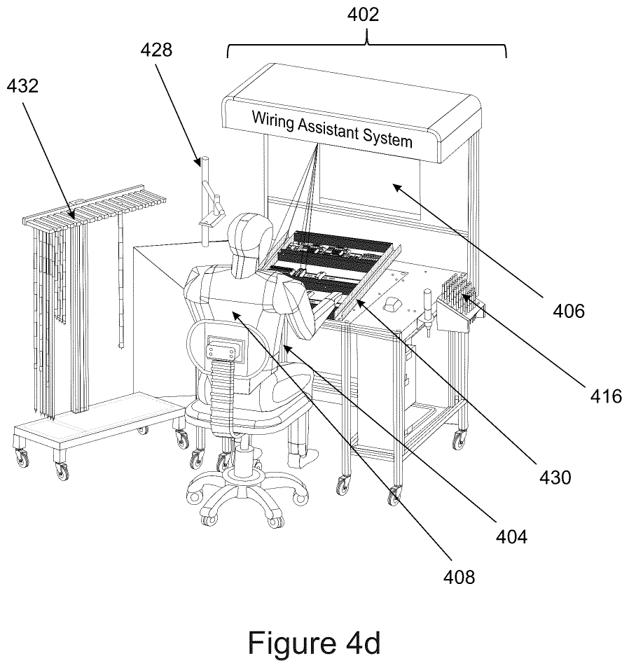

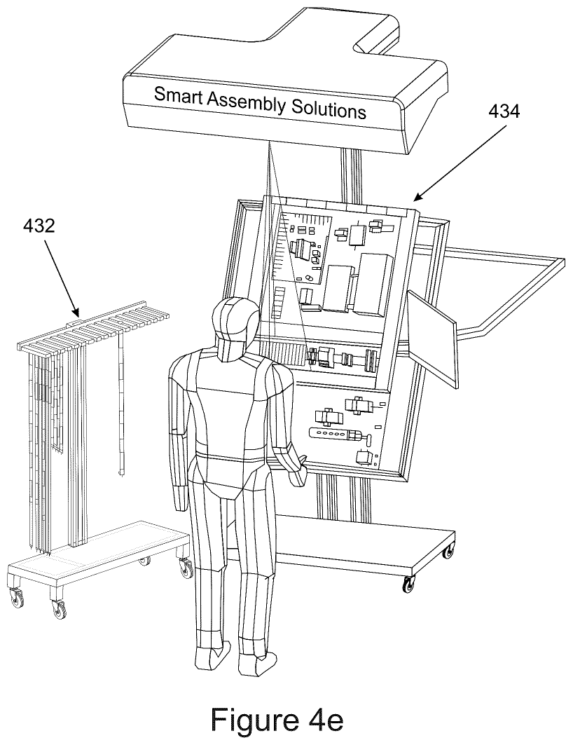

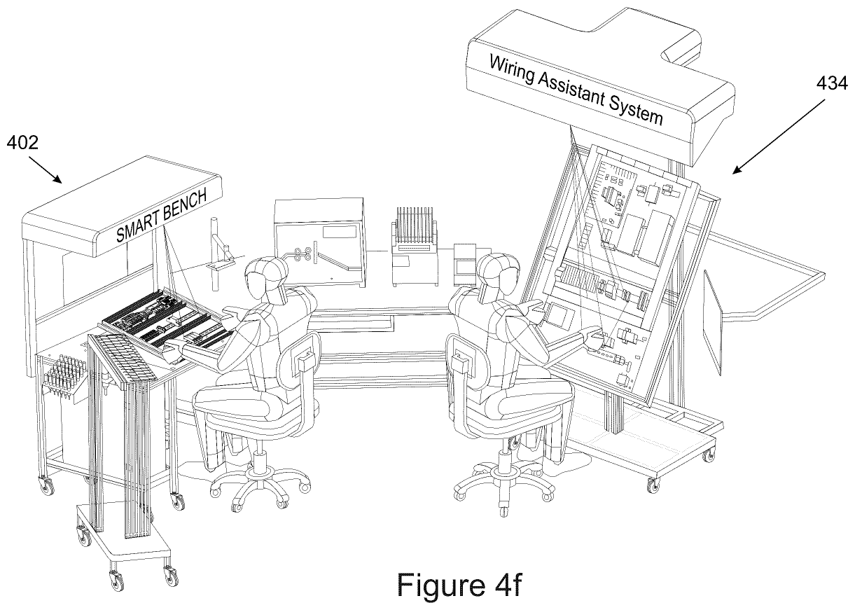

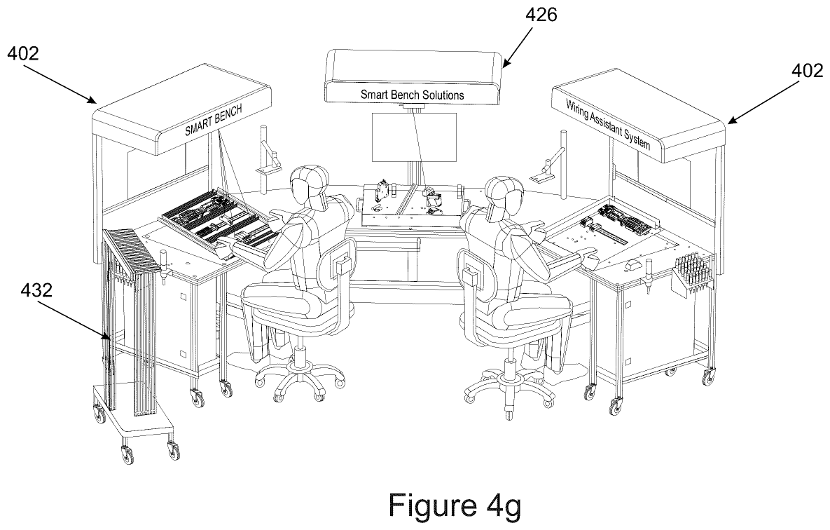

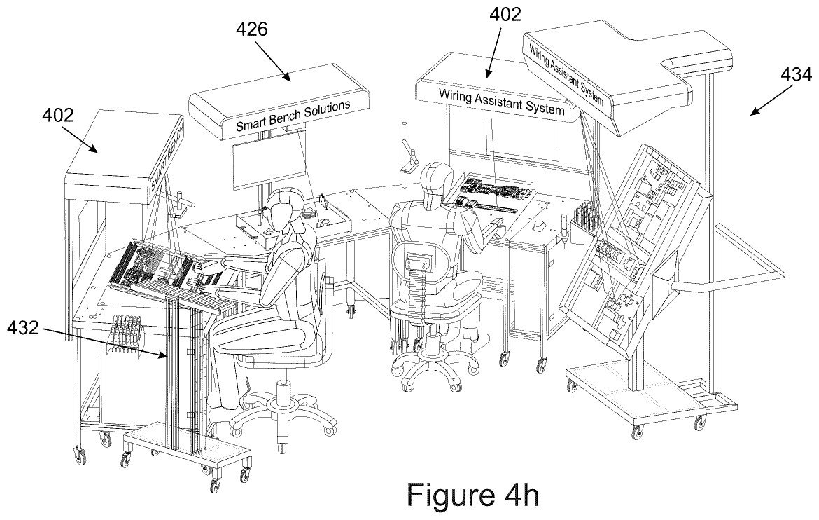

In some embodiments, as disclosed above, the mobile factories 104 includes one or more workbenches 202. Referring now to FIG. 4a, showing a schematic representation of an exemplary workbench 400, according to some embodiments of the invention. In some embodiments, an exemplary workbench comprises a wiring module 402 where the electrical panel 404 will be assembled/wired. In some embodiments, the wiring module 402 includes a screen 406 configured to show the user 408 instructions on how to assembly the electrical panel 404. In some embodiments, the wiring module 402 comprises a vision system 410 including one or more cameras 412 and optionally one or more lasers 414. In some embodiments, the vision system 410 is configured to monitor the actions performed by the user 408 on the electrical panel 404. In some embodiments, the actions are recorded and optionally sent to the central server for quality control purposes. In some embodiments, the optional one or more lasers 414 are part of a laser guiding system configured to guide/indicate the user 408 locations on the electrical panel 404 relevant to the wiring process, for example, where to position electrical elements in the electrical panel 404, show a pathway that a certain wire needs to do from one element to another in the electrical panel, etc. In some embodiments, the one or more lasers 414 indicate locations that are shown in the screen 406 as part of the instructions the user 408 receives from the workbench instruction module, which receives information from the central server. In some embodiments, alternatively a projector is used to project instruction to the user. In some embodiments, the workbench 400 further comprises all relevant instruments required for the wiring of electrical panels 404, for example, one or more accessories and/or tools 416, one or more wire roll feeder 418, one or more wire cutting machine 420, one or more strip and crimp machine 422 configured to strip the end of the wire and crimp a dedicated wire end, and optionally one or more printers 424 configured to print labels that are then attached to the wires and/or configured to print directly on the wire itself.

In some embodiments, the workbench are modular workbenches made of a plurality of exchangeable modules. In some embodiments, for example, the main module is the wiring module 402, as shown for example in FIG. 4a and in any of the FIGS. 4b-4h. In some embodiments, other exemplary modules can be one or more of the following modules:

Referring now to FIG. 4b, showing a schematic representation of an exemplary workbench comprising a wiring module and a mechanical assembly module, according to some embodiments of the invention. In some embodiments, an exemplary workbench includes a mechanical assembly module 426, configured for the assembly of elements in the electrical panel. In some embodiments, when a mechanical assembly module 426 is present, the assembly of the elements is performed in the mechanical assembly module 426 and the wiring is performed in the wiring module 402. In some embodiments, when a mechanical assembly module 426 is not present, both the assembly of the elements and the wiring are performed in the wiring module 402. In some embodiments, similar to the wiring module 402, the mechanical assembly module includes a vision system 410 including one or more cameras 412 and optionally one or more lasers 414.

In some embodiments, the workbench comprises one or more scanners configured to allow the user to scan the parts used in the wiring/assembly process. In some embodiments, the scanning is performed for one or more of the following reasons: to allow the user to be sure he is using the correct part, for monitoring of usage of consumables and for quality assurance purposes. In some embodiments, additionally, the system can indicate by, for example a laser, a projector, an image on the screen, voice cue, etc., what part to take next and where to put it in the assembly. In some embodiments, the part order may be assigned for efficiency and or ease of assembly.

Referring now to FIG. 4c, showing a schematic representation of an exemplary workbench comprising a movable wiring module, according to some embodiments of the invention. In some embodiments, the wiring module 402 comprises a movable part 430, for example, like a cart, configured to allow a user 408 to move the electrical panel being assembled/wired from one location to another inside the mobile factory.

Referring now to FIG. 4d, showing a schematic representation of an exemplary workbench comprising a ready-to-be-used wires module, according to some embodiments of the invention. In some embodiments, the workbench includes a ready-to-be-used wires module 432 comprising one or more ready to be used wires for example with end terminals and the right length. In some embodiments, ready to be used wires are brought in advance by the suppliers. In some embodiments, ready to be used wires are prepared according to the specific specification of the specific electrical panel, for example, knowing the electrical wiring plan, a plurality of wires is prepared and marked in advanced and the user picks up the required wire according to the instructions shown in the screen 406. In some embodiments, the user utilizes the scanner 428 to check that he is using the right wire according to the instructions.

Referring now to FIG. 4e, showing a schematic representation of an exemplary wiring module for electric cabinets 434, according to some embodiments of the invention. In some embodiments, the workbench comprises a dedicated wiring module for electric cabinets 434 configured to hold an electric cabinet, which are bigger than the electrical panels. In some embodiments, wiring module for electric cabinets 434 can be used in concomitance with wiring modules 402 dedicated to electrical panels, as shown for example in FIG. 4f. Additionally, also in FIG. 4f, it is shown 2 employees sharing some peripheral equipment (e.g. crimper, stripper, cable length cutter, etc.). In some embodiments, the system allows to share the equipment optimally by “feeding” the employee with the proper raw materials.

Referring now to FIGS. 4g-4h, showing exemplary configurations of exemplary modular workbenches, according to some embodiments of the invention. In some embodiments, as mentioned before, the workbench is a modular workbench and it can comprise any number of modules and any combinations of modules, as shown for example in FIG. 4g, showing two wiring modules 402 and one mechanical assembly module 426. Additionally, a ready-to-be-used wires module 432 is also shown. FIG. 4h shows two wiring modules 402, one mechanical assembly module 426, a ready-to-be-used wires module 432 and a wiring module for electric cabinets 434.

Referring now to FIG. 4i, showing a schematic representation of an exemplary workbench comprising a robotic arm module, according to some embodiments of the invention. In some embodiments, the workbench comprises a robotic arm module 436 configured to assist the user in the wiring and/or assembly actions performed on electrical cabinets/panels. In FIG. 4i, lightning electrical bodies are being assembled/wired, as an example of another product that can be assembled in the workbenches of the mobile factories. While the disclosure uses the example of preparation of electrical panels, it will be obvious to a person having skills in the art that other products can be prepared and assembled in similar mobile factories, and therefore, the following explanations, while directed to the assembly and preparation of electrical panels and/or cabinet, should not be limited to those alone, and other products are intended to be covered by the present invention, for example, electrical appliances, and any product that requires any level of assembly.

### Example of Exemplary Instructions Provided Via the Screen in an Exemplary Workbench

In some embodiments, as previously mentioned, the user receives wiring instructions via the screen and optionally using the laser guiding system. For example, the system can instruct the worker to perform one or more of the following actions: Pick a wire from the wire roll feeder 418, measure the necessary length and cut it (or the machine cut it to length and presents it to him), using the wire cutting machine 420, take a first end of the wire and insert in the strip and crimp machine 422, which strips the end of the wire and crimps, for example, a ferule at the stripped end. In some embodiments, optionally, the user is requested to test the ferrule on test jig/jaws. Then the user does the same for the second end of the wire. In some embodiments, optionally, the user is requested to add a label to wire by using the printer 424. Once the wire is ready for use, the system instructs the user to insert a first end of the wire into a first component in the electrical panel.

Optionally, the system requests the user to secure the wire and/or make sure the wire is secured in the first component, for example, by performing a pull test, where the user pulls the wire to see if it get loose from the first component. In some embodiments, the system then instructs the user to route the wire from the first component to a second component in the electrical panel. In some embodiments, optionally, the system uses the laser guiding system to show the route to the user on the electrical panel. In some embodiments, a potential advantage of showing the route using the laser guiding system is that the system can plan the route of multiple wires in advance and the user needs only to follow the instructions without thinking about the problem of the routing of the wire and/or overcrowding of din rails in the electrical panel.

In some embodiments, the system shown on the screen the whole route of the wire that is being placed. In some embodiments, the visual system monitors the routing in real-time to assess that the worker is performing the correct step of the process, for example, routing the wire in the correct pathway as instructed in the screen. In some embodiments, additionally, the work performed by the worker is recorded for quality assurance purposes. In some embodiments, the system then instructs the worker to insert second end into the second component, and then to test for continuity, for example, the system asks the user to touch two sides of the connected wire to check for continuity, for example by checking resistance on two ends. In some embodiments, optionally, continuity check can be complemented by a buzzer as customary in the art.

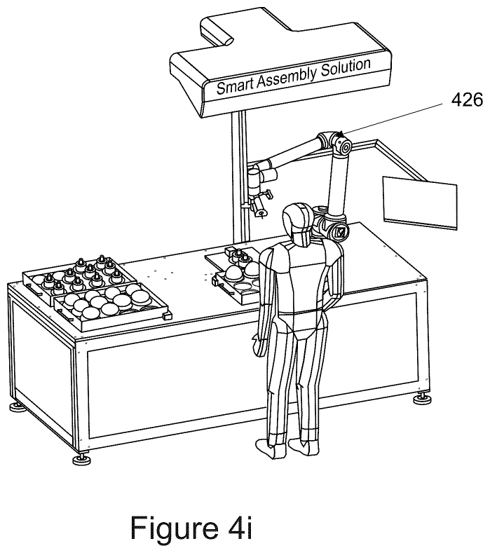

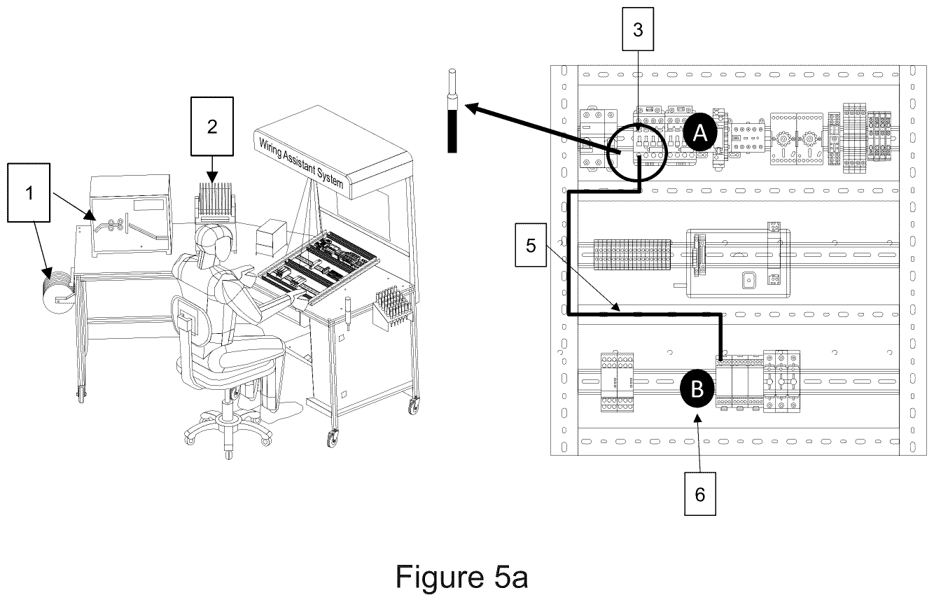

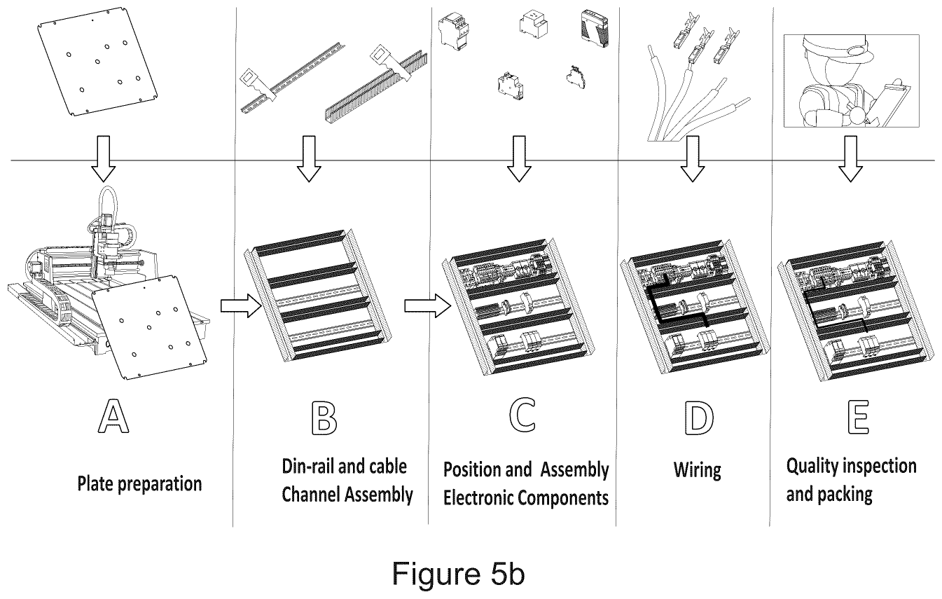

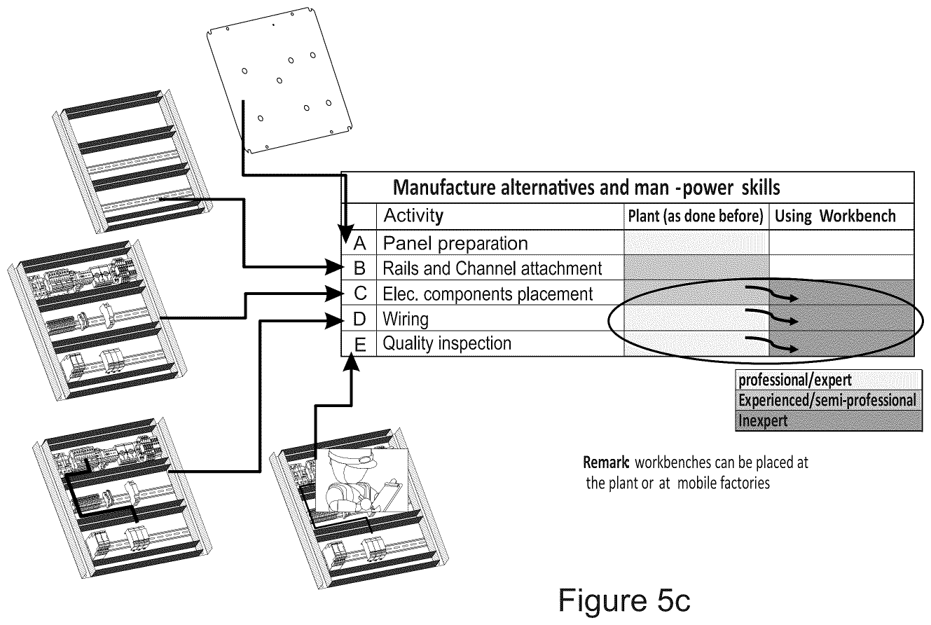

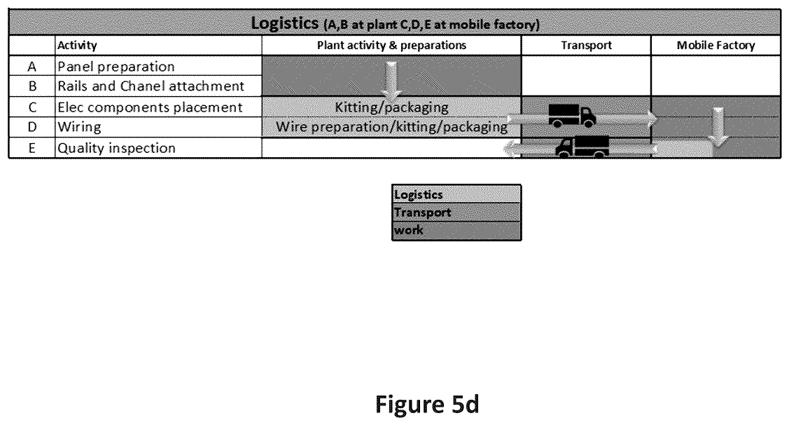

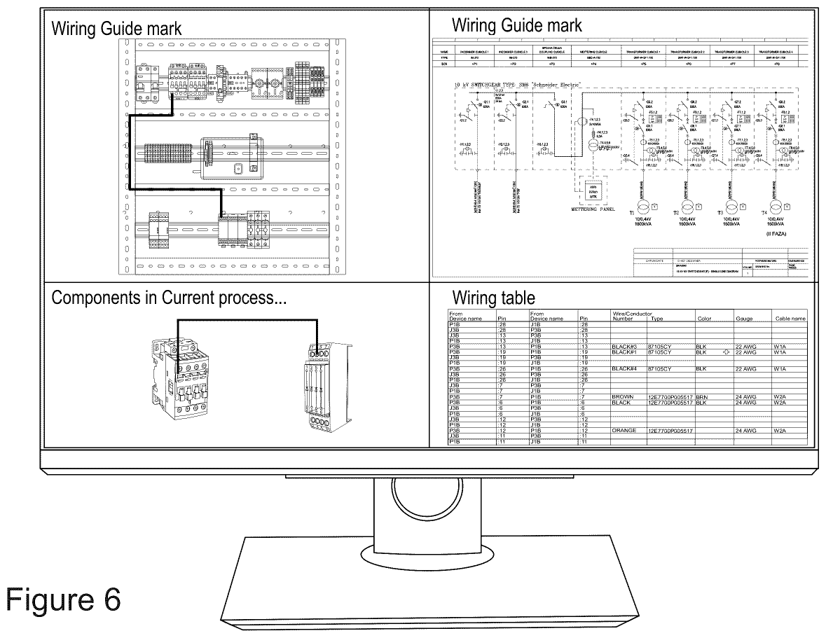

The following table, together with FIG. 5a as an example, summarize an exemplary instruction method performed by the system and transmitted to the worker via the screen (for example as shown in FIG. 6), the table showing what the instruction is, what the user is supposed to do, what is seen in the screen and what does the optional laser guiding system does.

| | | | Screen display | |
|---|---|---|---|---|
| # | Instruction | User action | & Audio | projector |
| 1 | Pick wire | Pick from | Display wire | Show which |
| | | wire roll | color, wire type | wire in wire |
| | | feeder and cut | and length info | roll feeder to |
| | | according to | | use |
| | | instruction | | |
| 2 | Add Ferrule | Insert wire | Enlarge view | Project mark |
| | to the ends | end to | of wire end | on crimper |
| | | crimping | inserted to | |
| | | machine to | crimper and | |
| | | add ferrule | optionally a | |
| | | | voice command | |
| | | | sounds the | |
| | | | instruction. | |
| 3 | Insert wire | Insertion | Show | Display circle |
| | to | | Component A | with laser on |
| | component | | in the | component A |
| | A | | schematic of | |
| | | | the electric | |
| | | | panel and | |
| | | | optionally | |
| | | | show video | |
| | | | showing | |
| | | | insertion of | |
| | | | wire into | |
| | | | component A | |
| 4 | pull test of | Perform pull | Show video of | Display circle |
| | wire in | test | the pull test | with laser on |
| | component | | | component A |
| | A | | | and arrow to |
| | | | | pull |
| 5 | Route cable | Route wire | Show plan on | Route display |
| | in ducts/din | | one side of | with laser |
| | | | screen; show | |
| | | | video of | |
| | | | routing on | |
| | | | other with | |
| | | | optionally a | |
| | | | voice command | |
| | | | explaining the | |
| | | | action | |
| | | | (optionally, the | |
| | | | user is allowed | |
| | | | to select | |
| | | | preferred | |
| | | | screen) | |
| 6 | Insert wire | Insertion of | Show | Display circle |
| | into | wire into | Component B | with laser on |
| | component | component B | on electrical | component B |
| | B | | panel and | |
| | | | optionally | |
| | | | show a video | |
| | | | of the insertion | |
| | | | into component | |
| | | | B | |
| 7 | pull test of | pull | Show video of | Display circle |
| | wire in | | the pull test | with laser on |
| | component | | | component B |
| | B | | | and arrow to |
| | | | | pull |

| | |
|---|---|
| repeat | New wire go to step 1 |

In some embodiments, part of the assembly is performed in one location and another part of the assembly is performed in a different location. Referring now to FIG. 5b, showing a schematic representation of the different parts of the assembly, according to some embodiments of the invention. The following example is provided to allow a person having skills in the art to understand the invention. Other and/or different parts of the process are intended to be part of the invention. In some embodiments, an exemplary assembly process comprises five distinct steps: plate preparation, din-rail and cable channel assembly, positioning and assembly of electronic components, wiring and performing QA and packaging of the final product. In some embodiments, all the assembly process steps are performed in a same location. In some embodiments, assembly process steps are performed in different locations. In some embodiments, when using different locations, dedicated logistic are in place to allow for a smooth movement of the products between mobile factories. In some embodiments, some activities related to the assembly process are either done in the mobile factories or are outsourced to third party suppliers. The table below provides an example of those activities:

In-house preparations

| | | Machines/special | |
|---|---|---|---|
| | Activity | equipment | Remarks |
| I | Plate preparation | Laser-cut/milling machines | can be outsourced |
| II | Rails and channels | Automatic saw | can be outsourced |
| | preparation | | |
| III | Components kitting | | |
| IV | wire preparation | Automatic wire cut/crimp | can be outsourced |
| | | machines | |

In some embodiments, the five distinct steps of an exemplary assembly process require different skill levels of the workers. Until now, all the steps were performed in the same factory by all very skilled personnel. In some embodiments, a potential advantage of the present invention is that it allows the use of alternative workers having different skill levels to perform the each of the steps. FIG. 5c shows a schematic representation of which steps can be performed using the mobile factories with the workbenches of the present invention.

In some embodiments, when performing steps in different locations, dedicated logistics are performed to allow the movement of the semi-finished products between locations. Referring now to FIG. 5d, showing a schematic representation of the logistics when using different location, according to some embodiments of the invention. In FIG. 5d can be seen that some activities are performed in the plant and some are performed in the mobile factory and the schematic truck showing the logistics performed in the process.

### Exemplary Remote Support/Supervision

In some embodiments, workers are optionally continuously supervised using the visual system 410. In some embodiments, the visual system 410 continuously records the actions performed by the worker in order to: confirm correct actions, record for performance evaluation of the worker, record for quality control and/or allow a supervisor and/or remote support to see what is happening in the workbench. In some embodiments, a supervisor/remote support is allowed to take control over the optional laser guiding system in order to show the worker what to do and/or to provide explanations. In some embodiments, remote assistance is performed using a video call in which the supervisor/remote assistance can see and talk to each other. In some embodiments, the worker activated the video call by pressing a dedicated button and/or menu in the system. In some embodiments, if the system detects that a certain worker is not performing according to predetermined quality standards, the system sends a notification to a supervisor, which is allowed to contact the worker and assess the situation.

### Exemplary Additional Information Regarding the Mobile Factories, the Workbenches and the Workers

In some embodiments, one key features of the invention is that the system is configured to provide detailed instructions to the worker, by using the screen and the optional laser guiding system. In some embodiments, a potential advantage of this feature is that it allows the recruitment of unexperienced personnel to perform assembly task or for example the assembling/wiring of the electrical panels/cabinets/etc. In some embodiments, the system further allows to teach a new worker the job and monitor his progress as he gains experience, but in general the system is pre-configured to the scenario where a new worker has absolutely no experience and everything is needed to be taught. In some embodiments, new workers are subjected to a training period where basic skills are assessed and progress is monitored.

In some embodiments, validation is an important feature of the system. In some embodiments, after each step (or at least after some steps) the user is instructed to perform a validation action that ensures the quality of the work. In some embodiments, in addition, everything is being recorded, which can be used either in real time or later for quality control. In some embodiments, the system comprises a dedicated software configured to automatically follow the actions performed by the worker and confirm that the actions are performed correctly. A good example of the video can be used for instruction—the system can edit multiple sections, optionally from multiple users, to one video.

In some embodiments, instructions and didactics are provided in various ways, for example, by using voice generated instructions and/or by showing videos. In some embodiments, the system is configured to perform training on the new workers and perform dedicated simulations to teach the actions to the new workers. In some embodiments, a worker is provided with the possibility to access a digital library and search for relevant training content. In some embodiments, for example, the worker is provided with a tool (for example a stylus), which is used to show the system the plan that the worker is suggesting. In some embodiments, the system is configured to evaluate the answer of the worker and either accept the plan or provide feedback/comments.

In some embodiments, the system is configured to allow 24 hours a day and 7 days a week access to workers to the mobile factories. In some embodiments, a potential advantage is that worker can choose when to do shifts, which potentially allows for a variety of population to work, for example, students, part-timers, mothers, handicap people, etc.

In some embodiments, the system allows for third party companies to request jobs to be done in the mobile factories. In some embodiments, third party companies provide specification of the assembly jobs required to be done. In some embodiments, explanations about the assembly process are generated either by the third party or by the managers of the system. In some embodiments, the system includes a group of supervisors/instructors/very experienced users that are responsible to the generation of teaching content, provide online remote support and remotely supervise the jobs (quality and quantity) that are being done. In some embodiments, supervisors/instructors/very experienced users can also be in site if needed.

In some embodiments, a potential advantage of using mobile factories is that it allows the managers of the system to position the mobile factories in the vicinity of the workers, for example, near universities, at parking lots, near shopping malls. In some embodiments, another potential advantage of positioning the mobile factories in those locations is that is can potentially encourage the workers to work and to work better. In some embodiments, additionally, it allows the workers to choose their shifts according to their needs. In some embodiments, the location of the mobile factories is additionally or alternatively based on optimized location for logistics.

In some embodiments, the system is configured to manage the work distribution between one or more of the availability of the workers, the different sites where the mobile factories are located and optionally based on individual performance of the workers (better workers can get better locations).

In some embodiments, in addition, the system is configured to distribute the work within a mobile factory by the level of skills of the individual workers. For example, skills related to the mechanical panel assembly, the wiring module and QA. In some embodiments, different workers can do different stages of the assembly according to their technical skills and experience. In some embodiments, the system monitors the skills and grade of the workers and may reward them accordingly.

In some embodiments, the system is configured to learn from the workers, the jobs done, the QA results and comments from the workers and the supervisors. For example, the system utilizes the information related to assembly and wiring and generates rules to ease and/or optimize the work. For example, a same component being positioned at a different location incurs saving time in the process; use of compatible components but different make (safe functionality) saves 20% labor cost but cost 10% more; calculating better costing of future job builds using actual database of costs per device and wires (for time to assemble and time to wire); evaluation of individual components to improve time of assembling (for example: statistically-a component from manufacturer A takes X seconds less to install than component from manufacturer B (where the components perform the same function). In some embodiments, the system is configured to optimize the work according to the individual skills of the workers.

In some embodiments, the system is configured to monitor the work in order to allow traceability of QA and record of build to standard. In some embodiments, this is important when working with unexperienced workers.

In some embodiments, the system is configured to monitor work continuity—for example, a certain electric panel can take several days to be ready. The system is configured to monitor the progress of each panel, so as to easily allow continuity of the work by a different worker.

In some embodiments, the system does not require to use both schematics and BOM drawing, as done with manual assembly. In some embodiments, the software uses the information to generate instructions and the worker does not need to handle the complexities of the wiring planning preparations.

In some embodiments, the system is configured to optimize the wiring routing to potentially save raw materials and time. In some embodiments, the optimization is performed by the system prior to commencing the guidance to the user.

In some embodiments, automation of generation of simple instructions are performed in order to exempt the use of experts/teachers.

In some embodiments, the system is configured to analyze and learn from all the jobs and eventually provide recommendations accordingly, for example recommend a better design to optimize space, assembly time and/or costs.

In some embodiments, as mentioned above, the system comprises a laser guiding system configured to assist in providing instructions and guiding the worker during the assembly/wiring process. In some embodiments, alternatively or additionally, the system provides video and/or voice instructions to the user. In some embodiments, the system is further configured to be interactive, for example, the system will ask questions to the worker to assess the status of the job. In some embodiments, the system provides video examples of the actions that the worker needs to perform. This is especially important when needing to assist in the assembly/wiring when an unexperienced worker is performing the actions. In some embodiments, the system is configured to record and monitor individual workers and utilize that information to provide improvements/suggestions to the worker in order to assist him in improving his work.

In some embodiments, the system is configured for teaching a new unexperienced worker by utilizing one or more of the following tools: using an expert and record dedicated videos/voice commands; using special tools (for example, a stylus which is used to touch and the system records) to generate wiring plan; learning from multiple process/examples; testing the worker with test assembly and scores to improve; creating an assembly plan; create a personal plan for individual workers according to their skills. In some embodiments, the system is configured for teaching to perform QA actions, for example, teach and execute QA operations with camera and smart tools with feedback from the tools and/or system. In some embodiments, it also includes requesting the worker to present sub parts to the camera and get confirmation for it.

In some embodiments, the system is configured to use programmable tools, for example, smart screwdriver, smart vices, smart pliers, and using led on tools and/or tool rack.

In some embodiments, the system further comprises virtual reality (VR) and augmented reality (AR) capabilities, used to assist the workers in their training and/or their normal operation during the assembly/wiring.

### Exemplary User Interface for Workers

In some embodiments, potential workers are provided with an app where first applications are filled. In some embodiments, after the worker is accepted, the worker uses the app to manage his working schedule. In some embodiments, the system uses the app also to provide payment to the workers. In some embodiments, the app allows the worker to see jobs that are coming, schedule their preferred time on job and sort the jobs per type (for example wiring assembly, mechanical assembly, QA and packaging). In some embodiments, the app is configured to allow sorting workers based on seniority, which is based on hours of work and quality of work. In some embodiments, the system provides priority based on seniority. In some embodiments, the app allows the worker to choose with whom to work (for example, work with friends). In some embodiments, the app allows for tax consolidated on system.

### Exemplary Logistics

In some embodiments, the system is configured to manage the logistics around the mobile factories. For example, each mobile factory requires to be supplied with the raw materials required for the assembly and wiring of the electrical panels. In some embodiments, logistics firms are allowed to use the app to schedule the delivery of the raw material and/or pickup finished goods and/or deliver finished goods. In some embodiments, the logistics comprises setting up the delivery of raw material to the mobile factories, shopping the finished goods to the end client. In some embodiments, the location of the mobile factories is calculated based on logistics demand (for example, raw material, finished goods, end customers, employees and schedule).

### Exemplary Logistics

In some embodiments, the system comprises a server configured for the management of the logistics, scheduling of workers and monitoring of required materials. For example, providing the required raw materials to the different locations, providing required tools and delivering finished goods to the end client. In some embodiments, the server, utilizing dedicated app/websites/software, includes multiple logistics suppliers. In some embodiments, the server comprises instructions to optimize the schedule for the different suppliers in order to meet the required schedule. In some embodiments, since the location of mobile factories can be chosen, the server further comprises instructions to find strategic locations that are easy to reach, not only for the workers, but also for the delivery companies that need to provide the required materials.

### Exemplary Setup of Instructions

In some embodiments, a potential issue to manage is how to easily generate instruction sets that are consistent, easy to use and can be expandable to new jobs. In some embodiments, the system solves this potential issue by the use of a dedicated application and database (DB) of operations along with analysis of examples and simulation. In some embodiments, newly generated sets of instructions are tested before actual use, with simulation engine and/or real users. In some embodiments, third party experts (for example, a group of users that are managed using the app) are recruited to generate instructions for the mobile factories.

### Exemplary Level of Skills of Workers

In some embodiments, a potential issue to manage is how to validate the employee skills to do a job. In some embodiments, the system solves this potential issue by testing the worker before starting a work, by rating workers by skill (when they come back), by teaching them while monitoring, using the vision module, the work with a dedicated software and remote intervention.

### Exemplary Monitoring of the Quality of the Work

In some embodiments, a potential issue to manage is how to guarantee quality of work. In some embodiments, the system solves this potential issue by monitoring the work as it is done. In some embodiments, additionally, the fact that detailed instructions are provided potentially guarantee the quality. In some embodiments, additionally, the system provides test routine in process, provides smart tools that measure work, provides remote and software monitor.

### Exemplary Safety

In some embodiments, a potential issue to manage is how to protect workers and equipment in the mobile factories. In some embodiments, the system solves this potential issue by generating the instruction with intrinsic care for safety. In some embodiments, additionally, random safety quiz are done to employees.

### Exemplary Theft Prevention of Finished Goods and Tools

In some embodiments, a potential issue to manage is how to monitor the consumables/raw materials in the mobile factories. It is known that workers can take tools or goods. In some embodiments, the system solves this potential issue by installing security cameras in the mobile factories, using smart lockers for tools, do checkout/check in process for tools used (for example, each tool with RFID); perform routine/daily count of consumables/raw materials and finished goods.

### Exemplary Methods

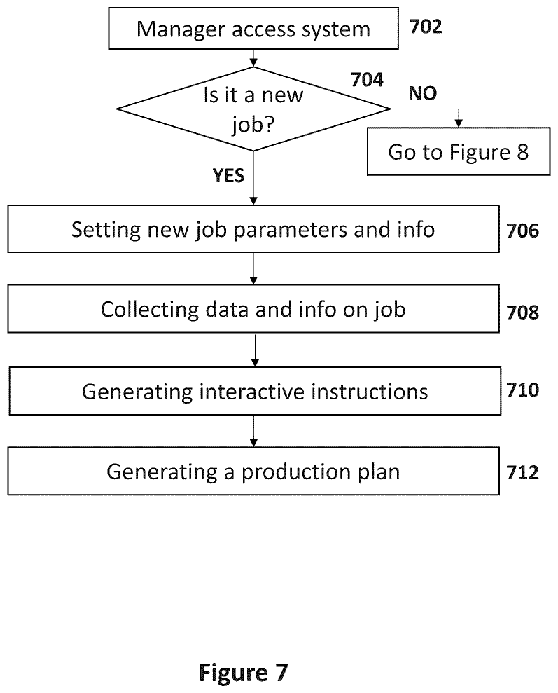

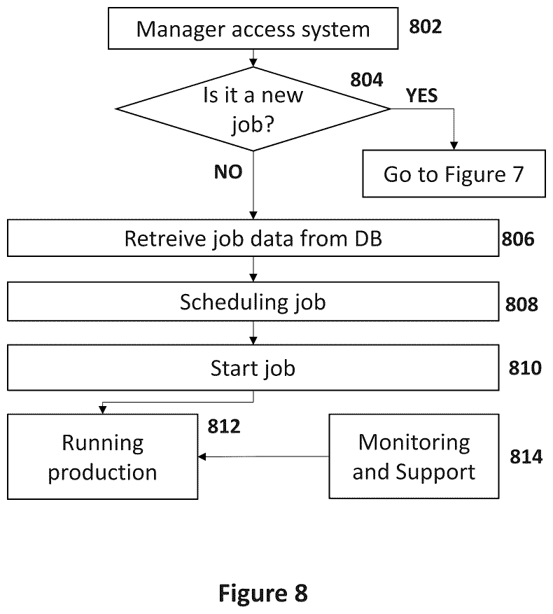

Referring now to FIG. 7, showing a flowchart of an exemplary method of setting a new job in the system, according to some embodiments of the invention. In some embodiments, a manager and/or any other authorized personnel access the system (central server 102) 702. In some embodiments, the system inquires if it is a new job 704. In some embodiments, if the answer is NO then flowchart continues in FIG. 8, see below. In some embodiments, if the answer is YES, then the user sets up the new parameters of the job and sets the required information required for the job 706. In some embodiments, the user collects the data/information for the job according to the previously set parameters and information 708.

In some embodiments, collecting data includes: engineering data (for example, drawings, schematics and/or BOM), assembly instructions and/or QA procedures/documents. In some embodiments, the user then generates the interactive instructions that will be shown to the worker 710. In some embodiments, the generation of the instructions includes one or more of using a library, using examples and generating instruction from the beginning. In some embodiments, when using a library, the library comprises instructions on how to generate an instruction sequence. In some embodiments, an instruction sequence comprises one or more of: building a sequence of operations, repeat the sequence of operations, providing the end of the instructions. In some embodiments, when building a sequence of operations, if a sequence of operations is already in the library, the user can then modify the sequence according to his needs.

In some embodiments, is no sequence of operations is found in the system, the user can then generate a new sequence of operations. In some embodiments, optionally, for each sequence of operations there will be a displayed text, a video, dedicated instructions for the laser guiding system, audio instructions, test and/or QA instructions and examples of special cases. In some embodiments, when using an example to generate an instruction sequence the user can use one or more of the following as examples: assembly videos retrieved from the library, generating new videos of an expert performing the assembly, using a simulation video from the library and/or as built by expert, recording audio instructions.

In some embodiments, alternatively or additionally, when using an example to generate an instruction sequence the user can use an AI algorithm to analyze and divide a video/example to operation steps (for example, by learning when an operation stars/end and/or when new raw material is used). In some embodiments, alternatively or additionally, when using an example to generate an instruction sequence the user can complement with a short operation clip with added instructions (for example, audio) based on what was learnt by the AI algorithm, based on what was learned from other instruction sets and/or based on what was learnt by an expert. In some embodiments, optionally, for each operation sequence generated there will be a displayed text, a video, dedicated instructions for the laser guiding system, audio instructions, test and/or QA instructions and examples of special cases. In some embodiments, as mentioned before, once the instruction sequence is provided, the user will add instructions to repeat the sequence as necessary, and then will provide end for the instruction sequence.

In some embodiments, setting tools and resources library includes one or more of: presence of tools (for example, screw drivers, pliers, etc.), providing tools with integrated feedback (for example torque screw drivers and/or electrical tools with sensors), providing general tools (for example bins and/or racks) and providing inspection tools (for example, cameras/lasers, gauges and special fixtures).

In some embodiments, setting support and supervision team includes one or more of: defining a supervisor level for job (for example, an expert employee, a technician and/or an engineer), recording sequence by supervision (optionally), providing matrix of comparison of multiple employees, providing direct link to workers on location, and providing link to logistics. Referring now to FIG. 8, showing a flowchart of an exemplary method of accessing a job in the system, according to some embodiments of the invention. In some embodiments, a manager and/or any other authorized personnel access the system (central server 102) 802. In some embodiments, the system inquires if it is a new job 804. In some embodiments, if the answer is YES then flowchart continues in FIG. 7, see below. In some embodiments, if the answer is NO, then the system retrieves the data of the specific job from the database 806. In some embodiments, retrieving the data includes one or more of an interactive instruction plan, a logistic plan, a standard time for job, a list of employees and a list of locations where job was done. In some embodiments, the user then schedules the job 808. In some embodiments, scheduling the job includes one or more of: setting a start time, setting a location, setting required tools and resources, setting workers schedule, setting a logistic plan which includes the delivery of tools and raw materials and planned delivery of finished goods, and setting support and supervision team. In some embodiments, the user then starts the job 810, which includes one or more of: validating the setup for the job, testing the workers skills by sample assembly-which leads to providing improved and/or remote instructions if needed, and performing QA tests. In some embodiments, the user then runs serial production for the job 812, which includes continuous monitoring and support 814. In some embodiments, monitoring a support includes one or more of monitoring worker performance (for example time and quality of the job), improving instructions if needed and generating dedicated DB with information regarding performance of the workers, for example by using parameters of performance.

In some embodiments, running a production and/or an operation library includes one or more of: assembling an operation library of actions (for example, insert, screw, glue, tighten and/or snap), and assembling QA operation actions (for example, visual inspection, auto-inspect (vision system) and measure with a certain tool for a certain parameter.

As used herein with reference to quantity or value, the term “about” means “within +20% of”.

The terms “comprises”, “comprising”, “includes”, “including”, “has”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular forms “a”, “an” and “the” include plural references unless the context clearly dictates otherwise. For example, the term “a compound” or “at least one compound” may include a plurality of compounds, including mixtures thereof.

Throughout this application, embodiments of this invention may be presented with reference to a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as “from 1 to 6” should be considered to have specifically disclosed subranges such as “from 1 to 3”, “from 1 to 4”, “from 1 to 5”, “from 2 to 4”, “from 2 to 6”, “from 3 to 6”, etc.; as well as individual numbers within that range, for example, 1, 2, 3, 4, 5, and 6. This applies regardless of the breadth of the range.

Whenever a numerical range is indicated herein (for example “10-15”, “10 to 15”, or any pair of numbers linked by these another such range indication), it is meant to include any number (fractional or integral) within the indicated range limits, including the range limits, unless the context clearly dictates otherwise. The phrases “range/ranging/ranges between” a first indicate number and a second indicate number and “range/ranging/ranges from” a first indicate number “to”, “up to”, “until” or “through” (or another such range-indicating term) a second indicate number are used herein interchangeably and are meant to include the first and second indicated numbers and all the fractional and integral numbers therebetween.

Unless otherwise indicated, numbers used herein and any number ranges based thereon are approximations within the accuracy of reasonable measurement and rounding errors as understood by persons skilled in the art.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A workbench for guided-assembling a product, comprising:
a. a surface on which said product is assembled;
b. at least one screen on which guiding-assembling instructions of an assembling process are shown;
c. circuitry comprising a memory and instructions to provide and monitor said guiding-assembling instructions of an assembling process through said at least one screen;
wherein said workbench further comprises a laser guiding system configured to guide a user during said assembling process.

2. The workbench according to claim 1, wherein said circuitry comprises instructions to monitor an execution of said assembling process for validating and/or improving one or more of: quality assurance (QA), cycle time and use of raw materials.

3. (canceled)

4. The workbench according to claim 1, further comprising at least one camera configured for monitoring actions performed during said assembling process.

5. The workbench according to claim 1, wherein said workbench is provided with a connection to at least one remote assistant for assisting in said assembling process.

6. The workbench according to claim 1, wherein said remote assistant has access to said at least one camera and said at least one screen.

7. The workbench according to claim 1, further comprising additional tools required for said assembling process.

8. The workbench according to claim 1, wherein said product is one or more of an electrical panel, an electrical cabinet, a lighting body and an electronic appliance.

9. The workbench according to claim 1, wherein said assembling process comprises wiring components in said product.

10. The workbench according to claim 1, wherein said instructions are generated based on optimized assembling process generated by one or more of: an expert, a computer having dedicated software comprising instructions to generate said optimized assembling process.

11. A mobile factory comprising:
a. a structure with a roof and walls sized and shaped to be mobilized from one location to another using at least one means of transportation;
b. one or more workbenches as disclosed in claim 1.

12. The mobile factory according to claim 11, wherein said at least one means of transportation is a truck.

13. A mobile factory system, comprising:
a. one or more mobile factories as disclosed in claim 11;
b. at least one central server comprising instructions to manage job activities and locations of said one or more mobile factories.

14. The mobile factory system according to claim 13, further comprising at least one remote assistant, for remotely assisting in assembling processes in said one or more mobile factories.
